(19) United States
(12) Patent Application Publication
(10) Pub. No.: US 2008/0303041 A1
(43) Pub. Date: Dec. 11, 2008

(54) Light emitting element, manufacturing method thereof and light emitting module using the same

(75) Inventor: Chih-Ming Lai, Pingtung City (TW)

Correspondence Address: BACON & THOMAS, PLLC, 625 SLATERS LANE, FOURTH FLOOR, ALEXANDRIA, VA, 22314-1176, US

(73) Assignee: LITE-ON TECHNOLOGY CORPORATION, Taipei (TW)

(21) Appl. No.: 12/153,097

(22) Filed: May 14, 2008

(30) Foreign Application Priority Data
Jun. 5, 2007 (TW) 96120230

(51) Int. Cl. H01L 33/00

(52) U.S. Cl. 257/89; 438/29; 257/E33.047; 257/E33.061; 257/E33.062

(57) ABSTRACT

A light emitting element, and a manufacturing method thereof, and a light emitting module using the same are provided. The light emitting element includes a first light emitting diode (LED), a second LED, a first electrode and a second electrode. The first LED is disposed on a substrate and has a first P-type semiconductor and a first N-type semiconductor. The second LED is disposed above the first LED and has a second P-type semiconductor and a second N-type semiconductor. The first electrode is electrically connected to the first P-type semiconductor and the second N-type semiconductor. The second electrode is electrically connected to the first N-type semiconductor and the second P-type semiconductor. The first electrode and the second electrode are electrically connected to an alternating current for driving the first LED and the second LED to emit light by turns.

This application claims the benefit of Taiwan application Serial No. 96120230, filed Jun. 5, 2007, the subject matter of which is incorporated herein by reference.

### BACKGROUND OF THE INVENTION

1. Field of the Invention

The invention relates in general to a light emitting element, a manufacturing method thereof and a light emitting module using the same, and more particularly to a light emitting element, a manufacturing method thereof and a light emitting module using the same suitable for use with alternating current.

2. Description of the Related Art

Light emitting diodes, which have the features of semiconductors, are capable of emitting light (cold luminescence) but different from fluorescent lamps or incandescent lamps. Light emitting diodes have advantages of small volume, less heat dissipation, lower power consumption, longer life cycle, shorter response time, and eco-friendliness. Moreover, the light emitting diodes are suitable for flat package and applicable in electronic devices to reduce their volume, thickness and weight. Nowadays, they have been used more and more to replace fluorescent and incandescent lamps, and are widely used in many products.

FIG. 1 is a diagram showing a conventional light emitting diode. The light emitting diode (LED) 900 includes a P-type semiconductor 900P, a N-type semiconductor 900N and a luminescence layer 900E. The luminescence layer 900E is disposed between the P-type semiconductor 900P and the N-type semiconductor 900N. When a bias voltage is applied to the LED 900, electrons and holes flow from the N-type semiconductor 900N and the P-type semiconductor 900P, respectively, into the luminescence layer 900E and then combine together, thereby generating light L9. The conventional LED 900 can only be activated via a direct current DC. If an alternating current is used to activate the LED 900, half amount of current is unused.

### SUMMARY OF THE INVENTION

It is therefore an object of the invention to provide a light emitting element, a manufacturing method thereof and a light emitting module using the same. By the stack structure and the way of electrical connection of a first light emitting diode (LED) and a second LED, the light emitting element has the advantages of being suitable for use with alternating current and capable of receiving high voltage. Also, the light emitting element has a small area to be occupied and high emitting efficiency. Moreover, the manufacturing procedure of the light emitting element is simplified, so that the light emitting element has a lower manufacturing cost, and the manufacturing yield of the light emitting element is high.

The invention achieves the above-identified object by providing a light emitting element that includes a first LED, a second LED, a first electrode and a second electrode. The first LED is disposed on a substrate and has a first P-type semiconductor, a first luminescence layer and a first N-type semiconductor, wherein the first luminescence layer is between the first N-type semiconductor and the first P-type semiconductor. The second LED is disposed above the first LED and has a second P-type semiconductor, a second luminescence layer, and a second N-type semiconductor, wherein the second luminescence layer is between the second N-type semiconductor and the second P-type semiconductor. The first electrode is electrically connected to the first P-type semiconductor and the second N-type semiconductor. The second electrode is electrically connected to the first N-type semiconductor and the second P-type semiconductor. The first electrode and the second electrode are electrically connected to an alternating current to activate the first LED and the second LED to emit light by turns.

The invention achieves the above-identified object by providing a light emitting module that includes a substrate and a plurality of light emitting elements. Each of the light emitting elements is disposed on the substrate and includes a first LED, a second LED, a first electrode and a second electrode. The first LED is disposed on a substrate and has a first P-type semiconductor, a first luminescence layer and a first N-type semiconductor, wherein the first luminescence layer is between the first N-type semiconductor and the first P-type semiconductor. The second LED is disposed above the first LED and has a second P-type semiconductor, a second luminescence layer and a second N-type semiconductor, wherein the second luminescence layer is between the second N-type semiconductor and the second P-type semiconductor. The first electrode is electrically connected to the first P-type semiconductor and the second N-type semiconductor. The second electrode is electrically connected to the first N-type semiconductor and the second P-type semiconductor. The first electrode and the second electrode are electrically connected to an alternating current to activate the first LED and the second LED to emit light by turns.

The invention achieves the above-identified object by providing a manufacturing method of a light emitting element. A first LED is formed, wherein the first LED has a first P-type semiconductor, a first luminescence layer and a first N-type semiconductor, and the first luminescence layer is between the first N-type semiconductor and the first P-type semiconductor. Then, a second LED is formed above the first LED, wherein the second LED has a second P-type semiconductor, a second luminescence and a second N-type semiconductor, and the second luminescence layer is between the second N-type semiconductor and the second P-type semiconductor. Next, a first electrode and a second electrode are formed; wherein the first electrode is electrically connected to the first P-type semiconductor and the second N-type semiconductor, and the second electrode is electrically connected to the first N-type semiconductor and the second P-type semiconductor.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1 is a diagram showing a conventional light emitting diode;

FIG. 2 is a diagram showing a light emitting element according to a first embodiment of the invention;

FIG. 3A is a diagram showing a direction of the current through the light emitting element in FIG. 2;

FIG. 3B is a diagram showing another direction of the current through the light emitting element in FIG. 2;

FIG. 4 is an equivalent circuit diagram of the light emitting element according to the first embodiment of the invention;

FIG. 5 is a flowchart showing the steps of a manufacturing method of the light emitting element according to the first embodiment of the invention;

FIGS. 6A to 6L sequentially show the structure of the light emitting element in the manufacturing process according to the first embodiment;

FIG. 7 is a diagram showing a light emitting element according to a second embodiment of the invention;

FIGS. 8A to 8M sequentially show the structure of the light emitting element in the manufacturing process according to the second embodiment;

FIG. 9 is a diagram showing a light emitting element according to a third embodiment of the invention;

FIGS. 10A and 10B sequentially show the structure of the light emitting element in the manufacturing process according to the third embodiment;

FIG. 11 is a diagram showing a light emitting element according to a fourth embodiment of the invention;

FIG. 12 is a diagram showing a light emitting module according to a fifth embodiment of the invention;

FIG. 13 is an equivalent circuit diagram of the light emitting module according to the fifth embodiment of the invention; and

FIG. 14 is an equivalent circuit diagram of a light emitting module according to a sixth embodiment of the invention.

### DETAILED DESCRIPTION OF THE INVENTION

### First Embodiment

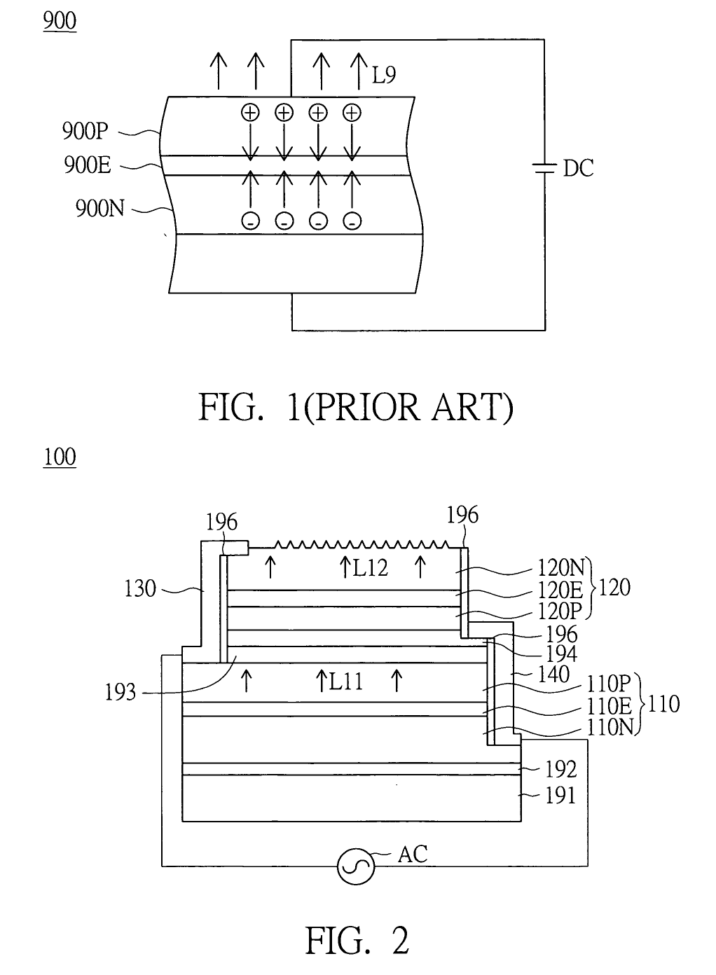

FIG. 2 is a diagram showing a light emitting element according to a first embodiment of the invention. The light emitting element 100 includes a first light emitting diode (LED) 110, a second LED 120, a first electrode 130 and a second electrode 140. The first LED 110 is disposed on a substrate 191, and has a first P-type semiconductor 110P and a first N-type semiconductor 110N. The second LED 120 is disposed above the first LED 110, and has a second P-type semiconductor 120P and a second N-type semiconductor 120N. The first electrode 130 is electrically connected to the first P-type semiconductor 110P and the second N-type semiconductor 120N. The second electrode 140 is electrically connected to the first N-type semiconductor 110N and the second P-type semiconductor 120P.

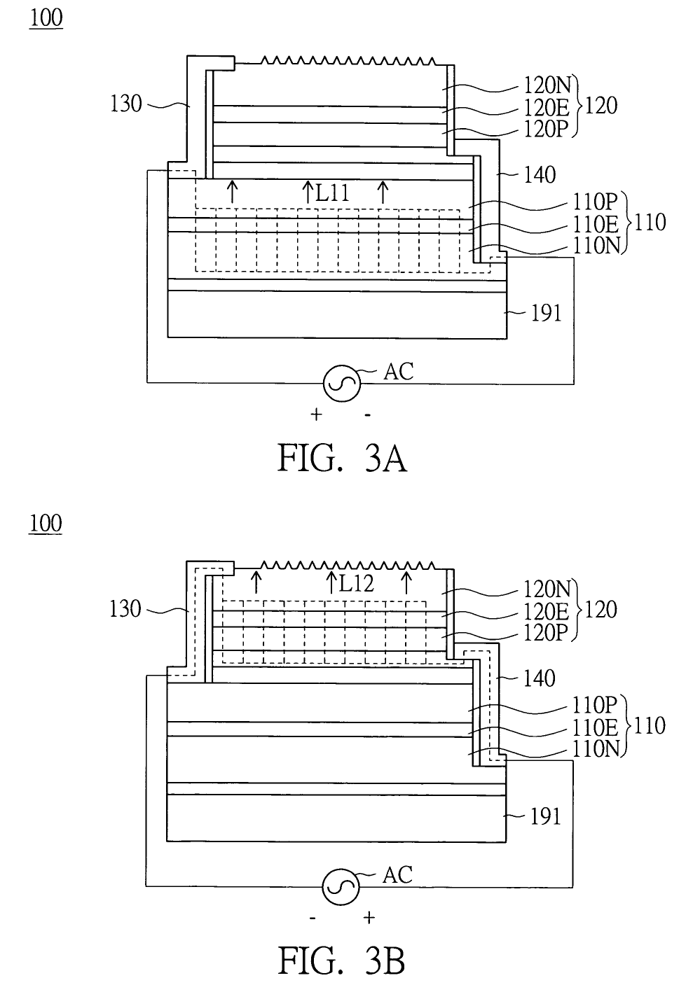

FIG. 3A is a diagram showing a direction of the current through the light emitting element in FIG. 2. The first electrode 130 and the second electrode 140 are electrically connected to an alternating current AC. In FIG. 3A, the alternating current AC applies a forward bias to the first electrode 130, and applies a reverse bias to the second electrode 140. In the first LED 110, the first P-type semiconductor 110P receives the forward bias and the first N-type semiconductor 110N receives the reverse bias, so that the first LED 100 is activated to emit a first color light L11. In the second LED 120, since the second P-type semiconductor 120P receives the reverse bias and the second N-type semiconductor 120N receives the forward bias, the second LED 120 does not emit light.

FIG. 3B is a diagram showing another direction of the current through the light emitting element in FIG. 2. In FIG. 3B, the alternating current AC applies a reverse bias to the first electrode 130 and a forward bias to the second electrode 140. In the first LED 110, the first P-type semiconductor 110P receives the reverse bias and the first N-type semiconductor 110N receives the forward bias, so that the first LED 100 does not emit light. In the second LED 120, since the second P-type semiconductor 120P receives the forward bias and the second N-type semiconductor 120N receives the reverse bias, the second LED 120 is activated to emit a second color light L12.

Under the two circumstances stated above, as the alternating current AC applies current in different directions to the light emitting element 100, it activates the first LED 110 and the second LED 120 to emit light by turns.

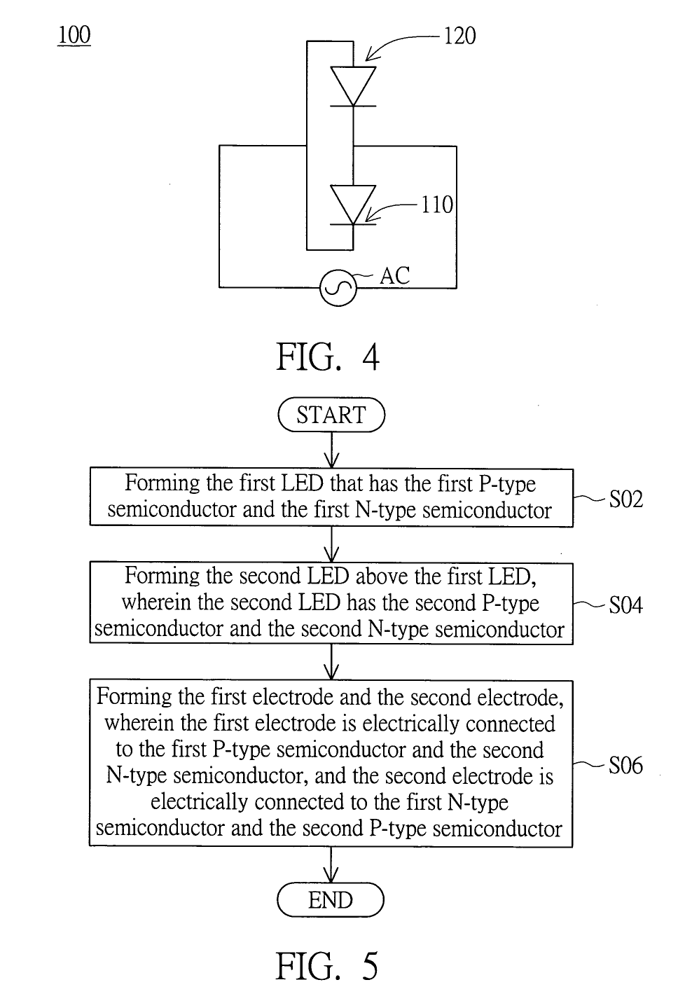

FIG. 4 is an equivalent circuit diagram of the light emitting element according to the first embodiment of the invention. The light emitting element 100 in the embodiment is equivalent to a circuit such that the first LED 110 and the second LED 120 are in a reversed parallel connection and electrically connected to the alternating current AC. No matter which the direction of the current supplied by the alternating current providing at any instant, either the first LED 110 or the second LED 120 is activated to emit light.

Moreover, the second LED 120 is not in parallel with the first LED 110 on the substrate 191, but rather, the second LED 120 is on top of the first LED 110, which halves the area that would be occupied by the light emitting element 100.

Also, as shown in FIG. 2, since the first LED 110 and the second LED 120 of the light emitting element 100 are stacked up in the same area, the same area is always emitting light owing either the first LED 110 or the second LED 120 is activated by the alternating current, increasing the efficiency of the light emitting element 100.

In FIG. 2, the light emitting element 100 further includes a barrier layer 192, a transparent dielectric layer 193, and a tunnel junction layer 194. The barrier layer 192 is disposed between the substrate 191 and the first LED 110. The transparent dielectric layer 193 is disposed over the first LED 110. The tunnel junction layer 194 is disposed between the transparent dielectric layer 193 and the second LED 120. The material of each layer in the stack structure of the light emitting element 100 is introduced in the following.

The substrate 191 is, for example, a Sapphire substrate, a silicon carbide (SiC) substrate, a silicon (Si) substrate, a gallium arsenide (GaAs) substrate, a lithium aluminium oxide (LiAlO₂) substrate, a magnesium oxide (MgO) substrate, a zinc oxide (ZnO) substrate, a gallium nitride (GaN) substrate, an aluminium nitride (AlN) substrate, or an indium nitride (InN) substrate. A designer can select a suitable material for fabricating the substrate 191 based on product functionality or the manufacturing process to be employed.

The first LED 110 further includes a first luminescence layer 110E that is between the first N-type semiconductor 110N and the first P-type semiconductor 110P. The first LED 110 is composed of a nitride semiconductor material. The material of the first N-type semiconductor 110N is, for example, gallium nitride doped with silicon (GaN:Si). The material of the first luminescence layer 110E is, for example, indium gallium nitride multiple quantum wells (InGaN MQWs). The material of the first P-type semiconductor 110P is, for example, gallium nitride doped with magnesium (GaN:Mg).

Preferably, the material of the transparent dielectric layer 193 has high transparency and low conductivity; it can be silicon oxide (SiO₂). The tunnel junction layer 194 is doped with P-type impurities or N-type impurities of high concentration. The material of the tunnel junction layer 194 can be indium gallium nitride doped with magnesium (InGaN:Mg).

The second LED 120 further includes a second luminescence layer 120E that is between the second N-type semiconductor 120N and the second P-type semiconductor 120P. The second LED 120 is composed of a nitride semiconductor material. The material of the second N-type semiconductor 120N is, for example, gallium nitride doped with silicon (GaN:Si). The material of the second luminescence layer 120E is, for example, indium gallium nitride multiple quantum wells (InGaN MQWs). The material of the second P-type semiconductor 120P is, for example, gallium nitride doped with magnesium (GaN:Mg). The first electrode 130 and the second electrode 140 are made of a material that is electrically conductive, and can be metal such as copper (Cu), aurum (Au), or aluminium (Al).

FIG. 5 is a flowchart showing the steps of a manufacturing method of the light emitting element according to the first embodiment of the invention. The manufacturing method of the light emitting element 100 includes at a minimum steps S02, S04, and S06. In step S02, the first LED 110 is formed, having the first P-type semiconductor 110P and the first N-type semiconductor 110N. Then, in step S04, the second LED 120 is formed above the first LED 110, having the second P-type semiconductor 120P and the second N-type semiconductor 120N. Next, in step S06, the first electrode 130 and the second electrode 140 are formed. The first electrode 130 is electrically connected to the first P-type semiconductor 110P and the second N-type semiconductor 120N. The second electrode 140 is electrically connected to the first N-type semiconductor 110N and the second P-type semiconductor 120P.

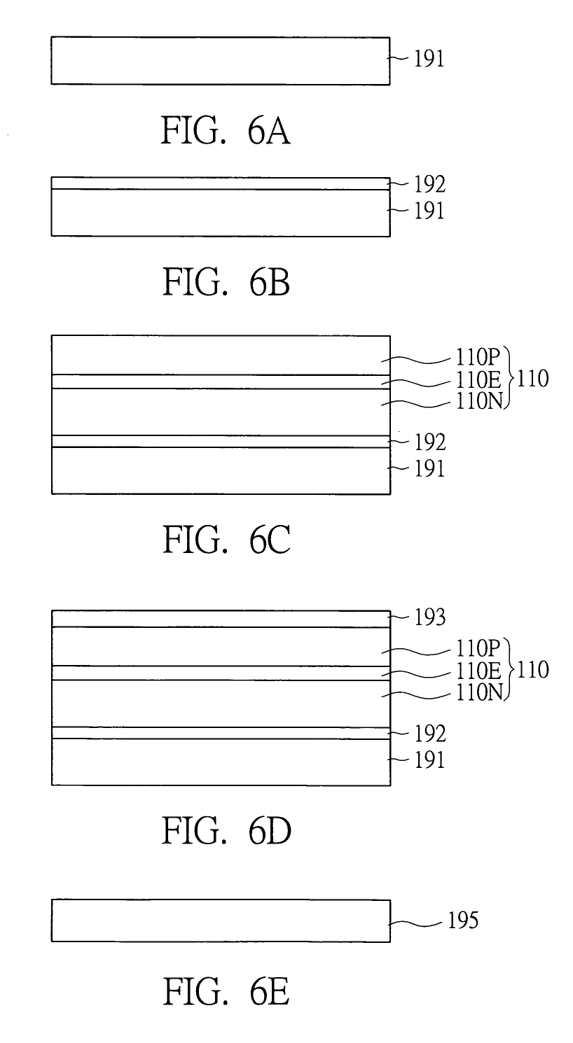

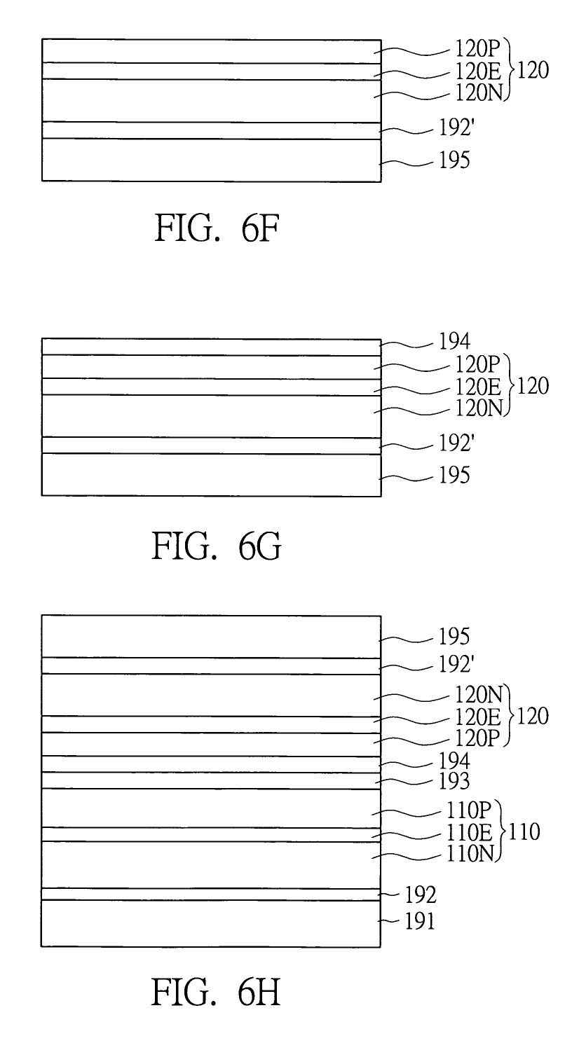

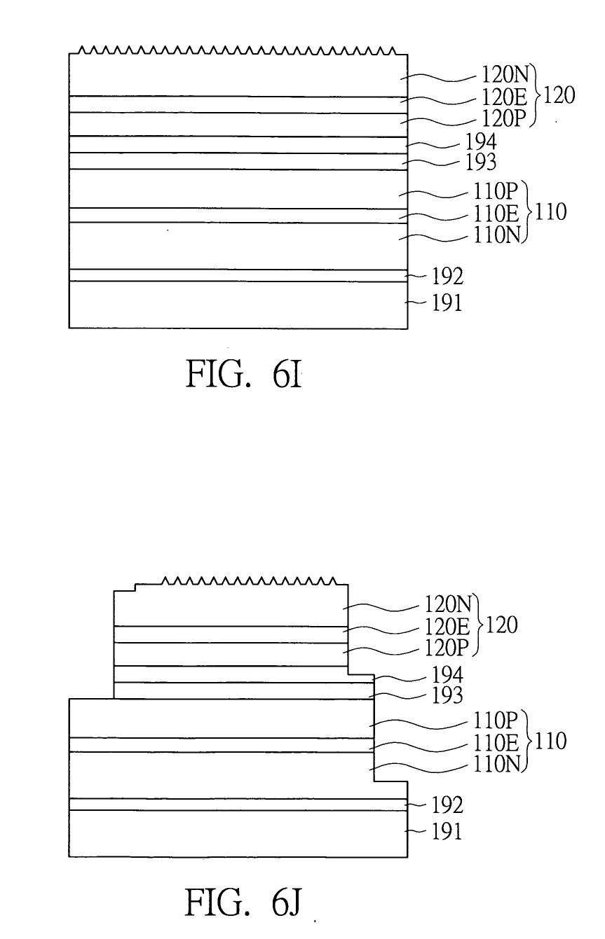

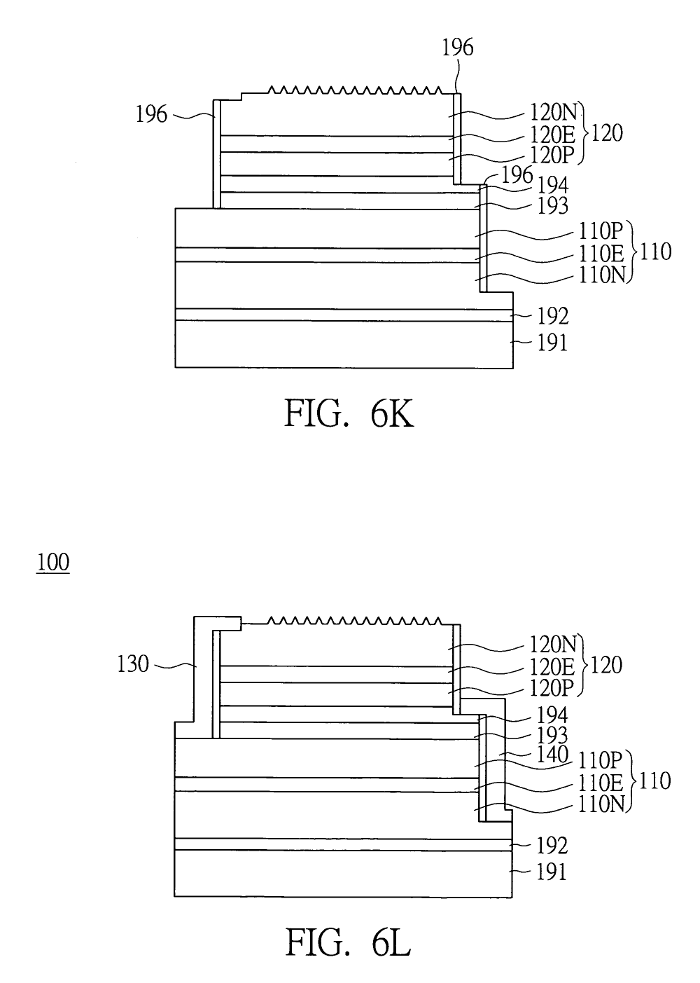

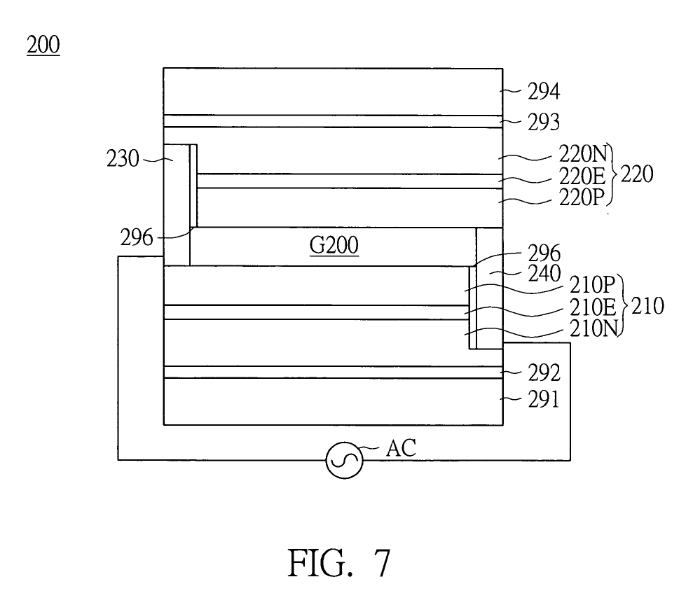

The manufacturing method of the light emitting element 100 is further elaborated with FIGS. 6A to 6L, which sequentially show the structure of the light emitting element in the manufacturing process according to the first embodiment. In FIG. 6A, a substrate 191 is provided. Then, as shown in FIG. 6B, a barrier layer 192 is formed over the substrate 191.

As shown in FIG. 6C, a first LED 110 is then formed over the barrier layer 192. The first LED 110 is formed by a single epitaxy, which is, for example, organometallic vapor phase epitaxy (OMVPE), molecular beam, epitaxy (MBE), or hydride vapor phase epitaxy (HVPE). A designer can choose a suitable way for growing a single epitaxy based on product functionality or manufacturing process. Next, in FIG. 6D, a transparent dielectric layer 193 is formed over the first LED 110. The step S02 in FIG. 5 is completed herein.

Next, as shown in FIG. 6E, another substrate 195 is provided. Proceeding to FIG. 6F, another barrier layer 192′ and a second LED 120 are formed on the substrate 195. The second LED 120 is formed by a single epitaxy, which may be, for example, organometallic vapor phase epitaxy (OMVPE), molecular beam epitaxy (MBE), or hydride vapor phase epitaxy (HVPE). A designer can choose a suitable method for growing a single epitaxy based on product functionality or manufacturing process.

Next, in FIG. 6G, a tunnel junction layer 194 is formed over the second LED 120. Then, as shown in FIG. 6H, the second LED 120 is disposed above the first LED 110 by bonding. Afterward, the substrate 195 and the barrier layer 192′ are removed, as shown in FIG. 6I. The step S04 in FIG. 5 is thusly completed.

In FIG. 6J, the first LED 110 and the second LED 120 are partially etched to expose parts of the first P-type semiconductor 110P, the first N-type semiconductor 110N, the second P-type semiconductor 120P, and the second N-type semiconductor 120N. Proceeding to FIG. 6K, an insulation layer 196 is formed on one side of the first LED 110 and the second LED 120.

Next, as shown in FIG. 6L, a first electrode 130 and a second electrode 140 are formed. The first electrode 130 is electrically connected to the first P-type semiconductor 110P and the second N-type semiconductor 120N. The second electrode 140 is electrically connected to the first N-type semiconductor 110N and the second P-type semiconductor 120P. The step S06 in FIG. 5 is thusly completed.

Performing the above steps completes the fabrication of the light emitting element 100 of the first embodiment. It is noted that the manufacturing method of the light emitting element 100 is not limited to the process shown in FIGS. 6A to 6L. The manufacturing method of the light emitting element 100 requires primarily the steps S02, S04, and S06; the process shown from FIGS. 6A to 6L is one of the embodiments of the light emitting element 100.

According to the manufacturing method of the light emitting element 110, the first LED 110 and the second LED 120 are stacked up by bonding. Moreover, the first electrode 130 and the second electrode 140 need no complicated wiring to be combined, simplifying the manufacturing procedure, reducing the manufacturing cost, and increasing the manufacturing yield.

Returning to FIG. 2, the first LED 110 emits the first color light L1, and the second LED 120 emits the second color light L12. The wavelength of the first color light L11 is greater than or equal to that of the second color light L12, so that the first color light L11 is not influenced by the second luminescence layer 120E when it passes through the second LED 120. The material of the first and second luminescence layers 110E and 120E is, for example, indium gallium nitride multiple quantum wells. The first color light L11 and the second color light L12 are blue, wherein the first color light L11 is a blue light that has a longer wavelength than the second color light L12. Preferably, the time period of the alternating current is smaller than the photogene time of the human eye. Therefore, whenever the alternating current activates the light emitting element 100, the light emitting element 100 appears to emit a steady and uniform blue light.

The first LED 110 and the second LED 120 have stack structures made of different material layers as illustrated above. However, the first N-type semiconductor 110N and the first P-type semiconductor 110P of the first LED 110 can be interchanged, and the second N-type semiconductor 120N and the second P-type semiconductor 120P of the second LED 120 can be interchanged as long as the first electrode 130 is electrically connected to the first P-type semiconductor 110P and the second N-type semiconductor 120N, and the second electrode 140 is electrically connected to the first N-type semiconductor 110N and the second P-type semiconductor 120P.

### Second Embodiment

FIG. 7 is a diagram showing a light emitting element according to a second embodiment of the invention. The light emitting element 200 of the second embodiment is different from the light emitting element 100 of the first embodiment due to the light emitting element 200 having a gap G200 between its LEDs. The light emitting element 200 has a substrate 291, a barrier layer 292, a first LED 210, a second LED 220, a barrier layer 293, and a substrate 294 sequentially stacked up. The gap G200 exists between the first LED 210 and the second LED 220 to prevent the first P-type semiconductor 210P of the first LED 210 from making contacting with the second P-type semiconductor 220P of the second LED 220. In addition, the gap G200 may be sealed with a transparent material such as silicone gel, resin or SOG (Spin On Glass) for sustaining the mechanical strength and preventing degradation due to exposure to the ambient.

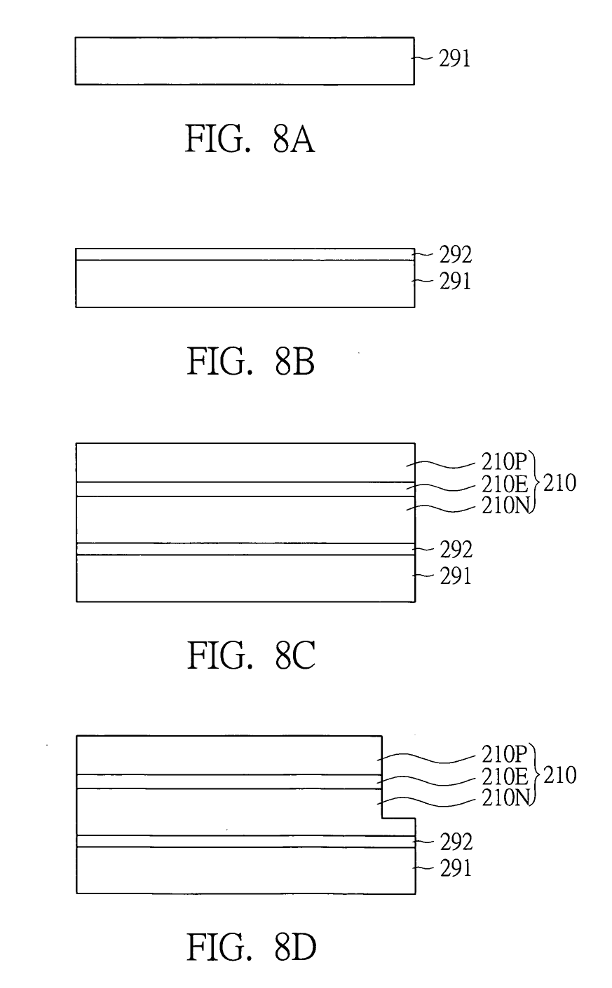

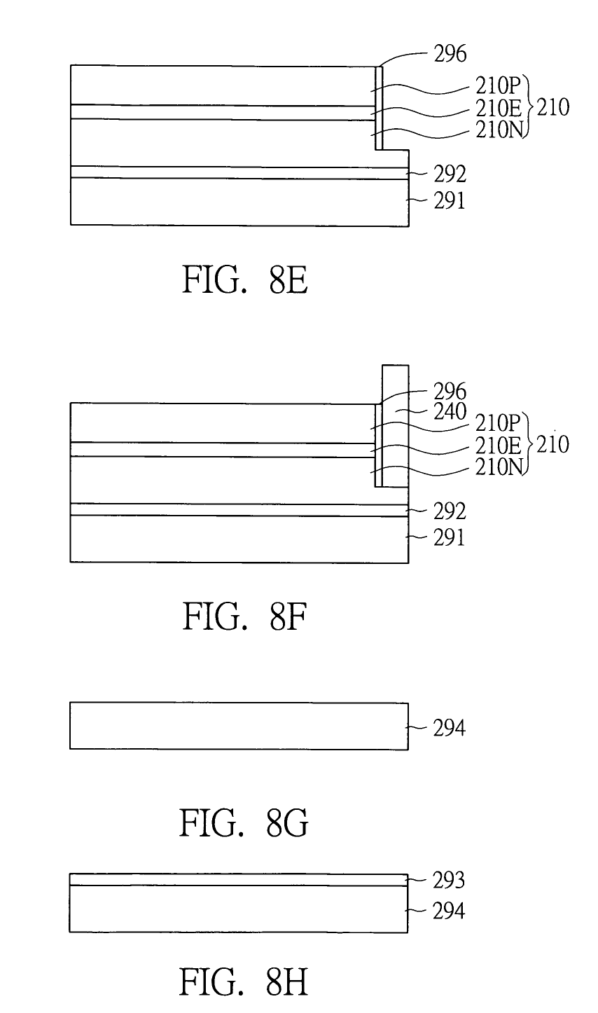

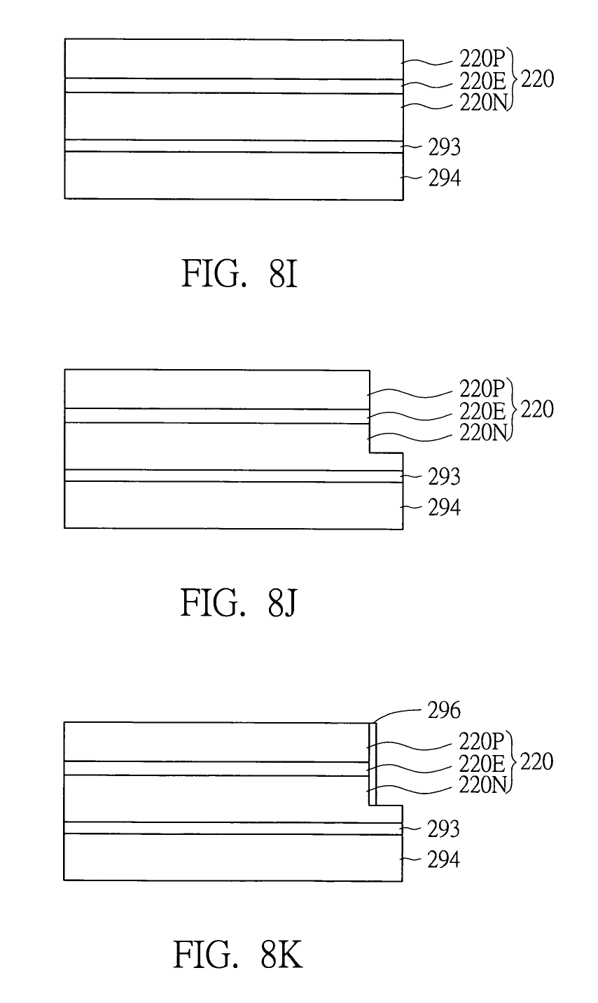

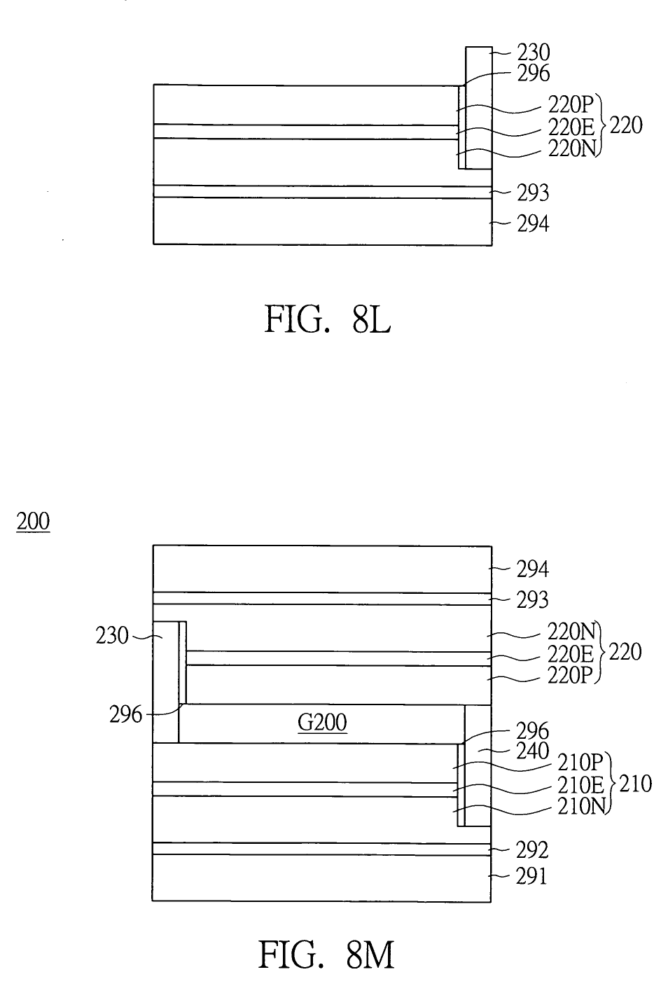

FIGS. 8A to 8M sequentially show the structure of the light emitting element in the manufacturing process according to the second embodiment. In FIG. 8A, a substrate 291 is provided. Then, as shown in FIG. 8B, a barrier layer 292 is formed over the substrate 291. Next, in FIG. 8C, a first LED 210 is formed over the barrier layer 292. Then, as shown in FIG. 8D, the first LED 210 is partially etched so as to expose part of the first N-type semiconductor 210N. Next, as shown in FIG. 8E, a transparent dielectric layer 293 is formed on one side of the first LED 210. Then, as shown in FIG. 8F, a second electrode 240 is formed over the exposed first N-type semiconductor 210N, wherein the top of the second electrode 240 is higher than that of the first N-type semiconductor 210N.

Next, as shown in FIG. 8G, another substrate 294 is provided. Then, in FIG. 8H, another barrier layer 293 is formed over the substrate 294. Next, in FIG. 8I, a second LED 220 is formed on the barrier layer 293. Then, in FIG. 8J, the second LED 220 is partially etched to expose part of the second N-type semiconductor 220N. Next, in FIG. 8K, an insulation layer 296 is formed on one side of the second LED 220. Then, in FIG. 8L, a first electrode 230 is formed over the exposed second N-type semiconductor 220N. The top of the first electrode 230 is higher than that of the second P-type semiconductor 220P. Next, in FIG. 8M, the first LED 210 is attached to the second LED 220. The first electrode 230 is electrically connected to the first P-type semiconductor 210P and the second N-type semiconductor 220N, and the second electrode 240 is electrically connected to the first N-type semiconductor 210N and the second P-type semiconductor 120P. Moreover, a gap G200 is located between the first LED 210 and the second LED 220. Furthermore, the gap G200 may be sealed with a transparent material such as silicone gel, resin or SOG (Spin On Glass) for sustaining the mechanical strength and preventing degradation due to exposure to the ambient.

By performing the above steps, the light emitting element 200 of the second embodiment is fabricated. It is noted that the manufacturing process of the light emitting element 200 is not limited to the process shown in FIGS. 8A to 8M.

### Third Embodiment

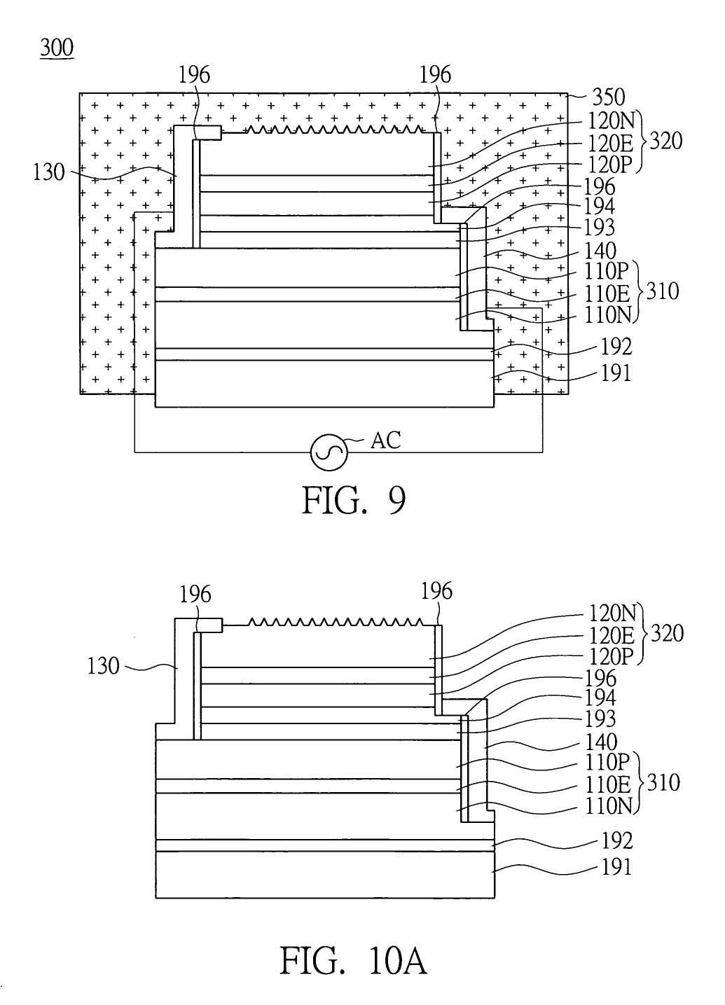

FIG. 9 is a diagram showing a light emitting element according to a third embodiment of the invention. The light emitting element 300 of the third embodiment is different from the light emitting element 100 of the first embodiment in that the light emitting element 300 includes a fluorescent layer covering its LED. Moreover, the color of the light emitted from the LEDs of the light emitting element 300 differs from that of the light emitted by the light emitting element 100.

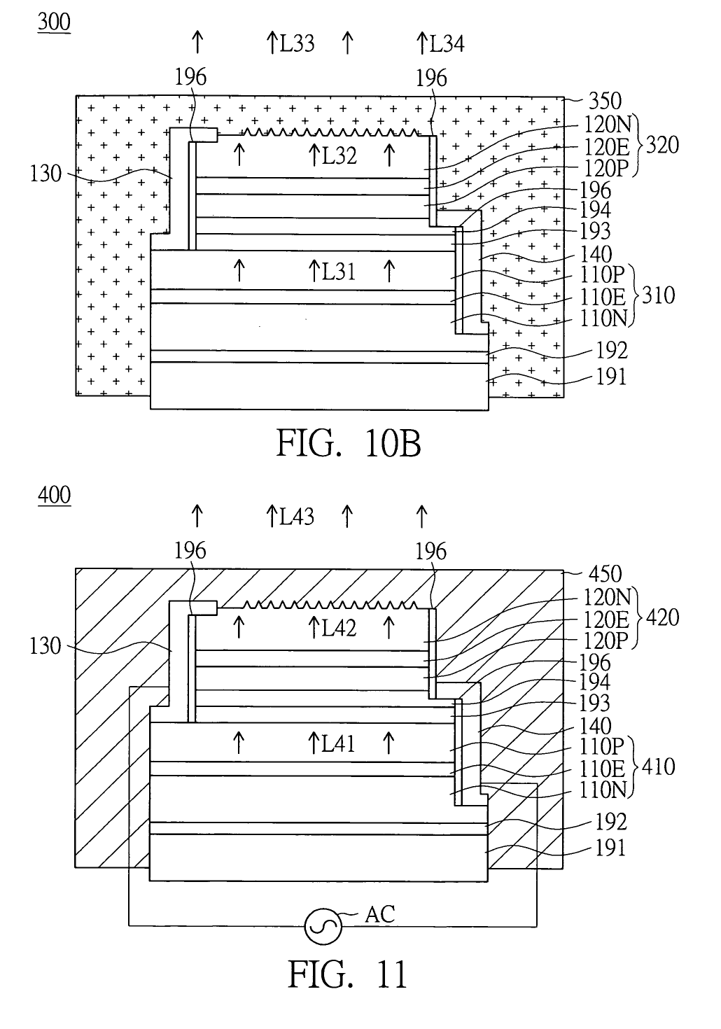

FIGS. 10A and 10B sequentially show the structure of the light emitting element in the manufacturing process according to the third embodiment. As shown in FIG. 10A, a first LED 310 and a second LED 320 are formed. The details of the steps have been elaborated in the first embodiment and are not repeated here. In FIG. 10B, a fluorescent layer 350 is formed over the second LED 320.

The first LED 310 emits a first color light L31, and the second LED 320 emits a second color light L32. The fluorescent layer 350 absorbs a portion of the first color light L31 and emits a third color light L33. Also, the fluorescent layer 350 absorbs a portion of the second color light L32 and emits a fourth color light L34. In the third embodiment, the first color light L31 is blue with a longer wavelength, the second color light L32 is blue with a shorter wavelength, and the third color light L33 and the fourth color light L34 are both yellow. Therefore, as alternating current activates the light emitting element 300, the light emitting element 300 emits a mixture of blue and yellow light which appears to the eye as white, as long as the period of the alternating current is less than the photogene time of the human eye. I

### Fourth Embodiment

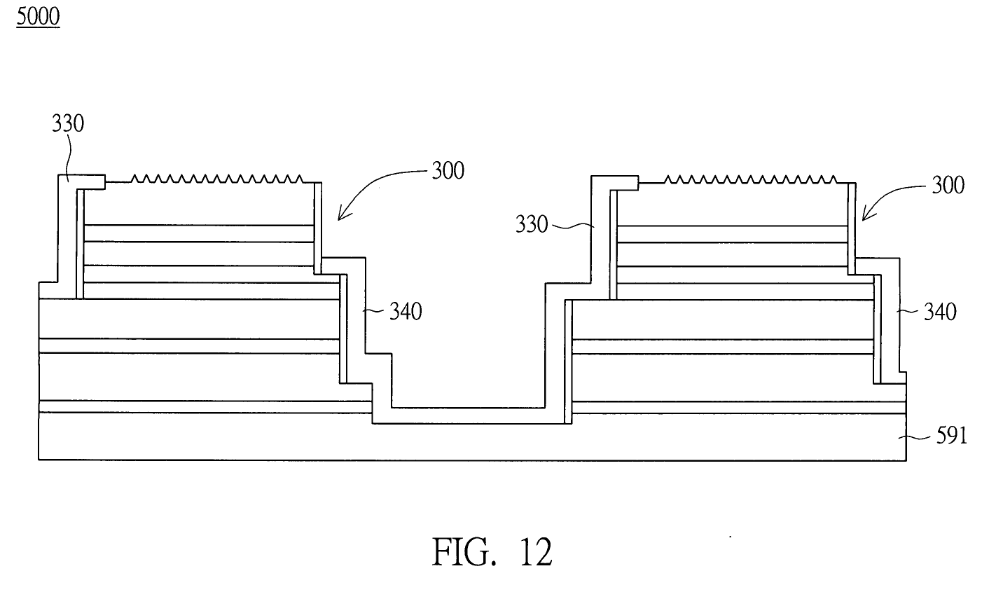

FIG. 11 is a diagram showing a light emitting element according to a fourth embodiment of the invention. The light emitting element 300 of the fourth embodiment differs from the light emitting element 300 in the color of the light emitted from the LEDs and the fluorescent layer.

As shown in FIG. 11, the first LED 410 emits a first color light L41, and the second LED 420 emits a second color light L42. The fluorescent layer 450 absorbs a portion of the first color light L41 or a portion of the second color light L42 to emit a third color light L43. In the embodiment, the first color light L41 is green, the second color light L42 is blue, and the third color light L43 is red. When an alternating current activates the light emitting element 400, the light emitting element 400 emits the first color light L41 and the second color light L42 by turns, and emits the third color light L43 at the same time. As long as the time period of the alternating current is less than the photogene time of human eye, the mixture of the first color light L41 (green), the second color light L42 (blue) and the third color light L43 (red) is interpreted by the eye as white light.

### Fifth Embodiment

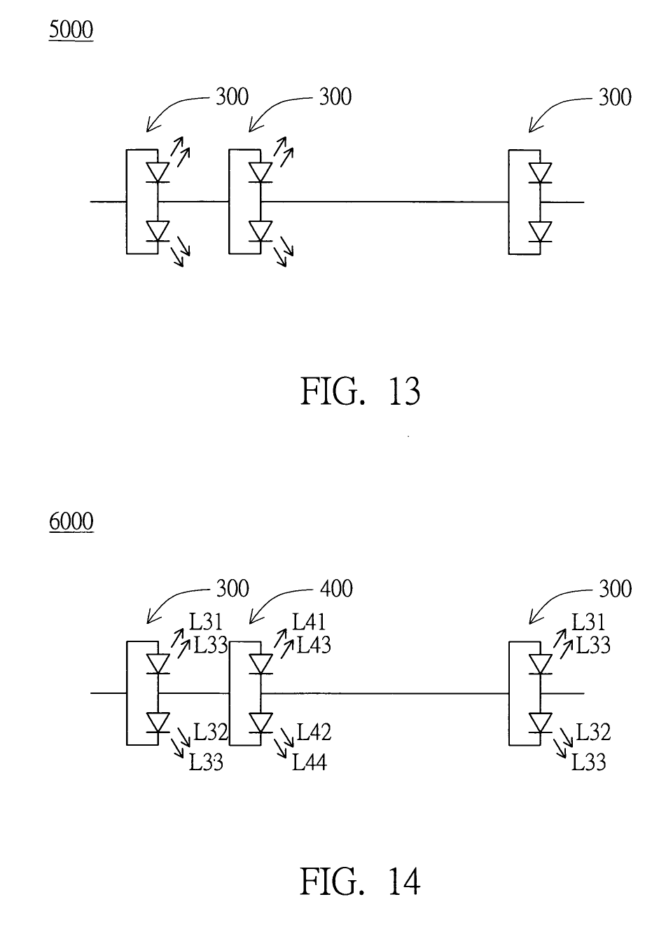

FIG. 12 is a diagram showing a light emitting module according to a fifth embodiment of the invention. Several light emitting elements 300 of the third embodiment are employed in a light emitting module and are not elaborated again. The light emitting module 5000 includes a substrate 591 and a plurality of light emitting elements 300 (only two are shown in FIG. 12), which are disposed on the substrate 591. In FIG. 12, the two light emitting elements 300 are connected in series, wherein the first electrode 330 of a light emitting element 300 is electrically connected to the second electrode 340 of another light emitting element 300. The manner of this connection is quite simple and needs no complicated wiring.

FIG. 13 is an equivalent circuit diagram of the light emitting module according to the fifth embodiment of the invention. Several light emitting elements 300 are in a series connection and are activated by an alternating current. The light emitting module 5000 is capable of operating at a high voltage (100 to 240 volts) without the use of any resistor, inductor, or capacitor.

### Sixth Embodiment

FIG. 14 is an equivalent circuit diagram of a light emitting module according to a sixth embodiment of the invention. The light emitting module 6000 in the sixth embodiment employs several light emitting elements 300 of the third embodiment and several light emitting elements 400 of the fourth embodiment. The light emitting elements 300 and 400 are connected in series. Preferably, the light emitting elements 300 and 400 are located alternately in the connection. When an alternating current activates the light emitting module 6000, it produces a white light that is a combination of the first color light L31, the second color light L32 and the third color light L33 of the light emitting elements 300, and the first color light L41, the second color light L42, the third color light L43 and the fourth color light L44 of the light emitting elements 400.

The light emitting element, the manufacturing method thereof, and the light emitting module using the same disclosed in the above embodiments have a first LED and a second LED stacked up and electrically connected, which enable the light emitting element to have advantages of which the following is a partial list.

The light emitting element is suitable for use with alternating current and needs no complicated wiring. As the alternating current activates the light emitting element, the light emitting element emits light continuously.

The light emitting module using the light emitting element is capable of receiving a high voltage (100 to 240 volts) without the use of any resistors, inductors, or capacitors, making the light emitting module quite convenient for many applications.

The first and second LEDs of the light emitting element are stacked up in the same area, so that the area occupied by the light emitting element is cut in half.

The light emitting element has high emitting efficiency since its LEDs are stacked up in the same area to emit light alternately when powered by alternating current.

Since the first and second LEDs of the light emitting element are stacked up and combined by means of bonding, they do not need any wiring design, and, as a result, the manufacturing procedure is simplified and the manufacturing cost is reduced.

The manufacturing yield also increases because the simplified manufacturing process reduces the number of the manufacturing steps, thereby reducing the chance of manufacturing defects caused by factors such as contaminating particles.

By incorporating with proper fluorescent layer on the first and second LEDs of the light emitting element, a uniform white light can be generated.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A light emitting element, comprising:
a first light emitting diode (LED) disposed on a substrate, having a first P-type semiconductor and a first N-type semiconductor;
a second LED disposed above the first LED, having a second P-type semiconductor and a second N-type semiconductor;
a first electrode electrically connected to the first P-type semiconductor and the second N-type semiconductor; and
a second electrode electrically connected to the first N-type semiconductor and the second P-type semiconductor;
wherein the first electrode and the second electrode are electrically connected to an alternating current to activate the first LED and the second LED to emit light by turns.

2. The light emitting element according to claim 1, wherein the first LED emits a first color light, and the second LED emits a second color light whose wavelength is smaller than or equal to that of the first color light.

3. The light emitting element according to claim 1, further comprising:
a tunnel junction layer disposed between the first LED and the second LED, wherein the tunnel junction layer is doped with P-type impurities or N-type impurities of high concentration.

4. The light emitting element according to claim 1, further comprising:
a transparent dielectric layer disposed between the first LED and the second LED.

5. The light emitting element according to claim 1, further comprising:
a fluorescent layer disposed over the second LED.

6. The light emitting element according to claim 5, wherein the first LED emits a first color light, the second LED emits a second color light, the fluorescent layer absorbs a portion of the first color light or a portion of the second color light to emit a third color light, which is mixed with the first and second color lights to generate a white light.

7. The light emitting element according to claim 6, wherein the time period of the alternating current is smaller than the photogene time of the human eye.

8. The light emitting element according to claim 5, wherein the first LED emits a first color light, the second LED emits a second color light, the fluorescent layer absorbs a portion of the first color light to emit a third color light, which is mixed with the first color light to generate a white light, and the fluorescent layer absorbs a portion of the second color light to emit a fourth color light that is mixed with the third color light to generate another white light.

9. The light emitting element according to claim 1, wherein a gap exists between the first LED and the second LED.

10. The light emitting element according to claim 9, wherein the gap is sealed with a transparent material.

11. A light emitting module, comprising:
a substrate; and
a plurality of light emitting elements disposed on the substrate, wherein each of the light emitting elements includes:
a first LED disposed on the substrate, having a first P-type semiconductor and a first N-type semiconductor;
a second LED disposed above the first LED, having a second P-type semiconductor and a second N-type semiconductor;
a first electrode electrically connected to the first P-type semiconductor and the second N-type semiconductor; and
a second electrode electrically connected to the first N-type semiconductor and the second P-type semiconductor;
wherein the first electrode and the second electrode are electrically connected to an alternating current to activate the first LED and the second LED to emit light by turns.

12. The light emitting module according to claim 11, wherein the light emitting elements are connected in series.

13. The light emitting module according to claim 11, wherein the first LED emits a first color light, and the second LED emits a second color light whose wavelength is smaller than or equal to that of the first color light.

14. The light emitting module according to claim 11, wherein each of the light emitting elements further comprises:
a tunnel junction layer disposed between the first LED and the second LED, wherein the tunnel junction layer is doped with P-type impurities or N-type impurities of high concentration.

15. The light emitting module according to claim 11, wherein each of the light emitting elements further comprises:
a transparent dielectric layer disposed between the first LED and the second LED.

16. The light emitting module according to claim 11, wherein each of the light emitting elements further comprises:
a fluorescent layer covering the second LED.

17. The light emitting module according to claim 16, wherein the first LED emits a first color light, the second LED emits a second color light, the fluorescent layer absorbs a portion of the first color light or a portion of the second color light to emit a third color light, which is mixed with the first and second color lights to generate a white light.

18. The light emitting module according to claim 17, wherein the time period of the alternating current is smaller than the photogene time of the human eye.

19. The light emitting module according to claim 16, wherein the first LED emits a first color light, the second LED emits a second color light, the fluorescent layer absorbs a portion of the first color light to emit a third color light, which is mixed with the first color light to generate a white light, and the fluorescent layer also absorbs a portion of the second color light to emit a fourth color light that is mixed with the third color light to generate another white light.

20. The light emitting module according to claim 11, wherein a gap exists between the first LED and the second LED and the gap is sealed with a transparent material.

21. A manufacturing method of a light emitting element, comprising:
forming a first light emitting diode (LED), wherein the first LED has a first P-type semiconductor and a first N-type semiconductor;
forming a second LED above the first LED, wherein the second LED has a second P-type semiconductor and a second N-type semiconductor; and
forming a first electrode and a second electrode, wherein the first electrode is electrically connected to the first P-type semiconductor and the second N-type semiconductor, and the second electrode is electrically connected to the first N-type semiconductor and the second P-type semiconductor.

22. The manufacturing method according to claim 21, wherein the first LED and the second LED are formed by a single epitaxy.

23. The manufacturing method according to claim 21, wherein the second LED is disposed above the first LED by bonding.

24. The manufacturing method according to claim 21, further comprising:
forming a tunnel junction layer above the first LED after the step of forming the first LED, wherein the tunnel junction layer is doped with P-type impurities or N-type impurities of high concentration.

25. The manufacturing method according to claim 21, further comprising:
forming a transparent dielectric layer above the first LED after the step of forming the first LED.

26. The manufacturing method according to claim 21, further comprising:
forming a fluorescent layer above the second LED after the step of forming the second LED.
